(19) United States
(12) Patent Application Publication
(10) Pub. No.: US 2026/0060132 A1
(43) Pub. Date: Feb. 26, 2026

(54) DISPLAY DEVICE

(71) Applicant: LG Display Co., Ltd., Seoul (KR)

(72) Inventors: SungJin KIM, Paju-si (KR); SangYun LEE, Paju-si (KR); Juheon HYEON, Paju-si (KR)

(73) Assignee: LG Display Co., Ltd., Seoul (KR)

(21) Appl. No.: 19/285,650

(22) Filed: Jul. 30, 2025

(30) Foreign Application Priority Data
Aug. 20, 2024 (KR) 10-2024-0110978

(51) Int. Cl. H01L 23/31; H10D 86/60

(52) U.S. Cl. CPC H01L 23/3121; H10D 86/60

(57) ABSTRACT

A display device includes a stack portion, a cover glass on the stack portion, a side sealing portion on a side surface of the stack portion, and a coating layer disposed between the stack portion and the side sealing portion. The coating layer includes a hydrophobic material having low surface energy, which reduces adhesion to the side sealing portion and mitigates stress transfer. The stack portion includes a substrate, and an intermediate layer on the substrate, the intermediate layer including a sub intermediate layer and a lower adhesive layer on the sub intermediate layer. By buffering thermal expansion or contraction differences between the stack portion and the side sealing portion, the coating layer helps prevent mechanical stress accumulation that could otherwise result in cracks or delamination. This structure enhances the reliability and durability of the display panel, particularly under thermal cycling, thereby preventing abnormal deformation and improving overall device lifespan.

### CROSS-REFERENCE TO RELATED APPLICATION

This application claims priority from Korean Patent Application No. 10-2024-0110978, filed on Aug. 20, 2024, which is hereby incorporated by reference for all purposes as if fully set forth herein.

### BACKGROUND

### Technical Field

Embodiments of the disclosure relate to a display device.

### Description of the Related Art

Display devices are applied to various electronic devices, such as TVs, mobile phones, laptops, and tablets. Display devices include organic light emitting displays (OLEDs), which are self-emissive, and liquid crystal displays (LCDs), which require a separate light source.

Meanwhile, a display device may have a structure in which various insulation layers and various metal layers are stacked.

### BRIEF SUMMARY

The inventors of the present disclosure have recognized that, in a stacked structure, the side surfaces of the stack may be particularly vulnerable to external impact. Additionally, when the display device includes an organic layer formed from organic materials, that layer may be more susceptible to degradation caused by exposure to oxygen or moisture. Such deterioration can lead to a shortened lifespan of the display device and degraded image quality.

Various embodiments of the display device are directed to the use of a hydrophobic coating layer positioned between the stack portion and the side sealing portion to mitigate mechanical stress resulting from differential thermal expansion or contraction. By using materials such as fluorine-based, silicon-based, or saturated alkyl-based hydrophobic polymers with low surface energy, the coating layer effectively decouples the thermal behavior of adjacent layers. This prevents stress concentration at critical interfaces—especially between the sub intermediate layer and lower adhesive layer—reducing the risk of cracks or delamination during temperature fluctuations, including thermal shock conditions commonly encountered during manufacturing.

Additionally, in bent regions of the display, inner and outer coating layers are used to balance compressive and tensile stresses, further enhancing structural integrity. The inventive structure ensures the coating layer adheres more strongly to the stack portion than to the sealing materials, allowing it to move in concert with the stack during thermal changes while isolating the impact of the sealing layers. This design increases panel durability, improves manufacturing yield, and enhances the reliability of flexible and foldable display devices.

Embodiments of the disclosure may provide a display device having a side sealing portion as a structure for protecting a side portion of a stack portion in a display panel from external impact.

Embodiments of the disclosure may provide a display device further including a coating layer as a structure to address cracks and/or delamination in an interlayer interface portion during a change in temperature, due to differences in coupling characteristics between a side sealing portion and each layer included in a stack portion in a display panel.

Embodiments of the disclosure may provide a display device capable of more effectively preventing cracks and/or delamination in an interlayer interface portion in a display panel by disposing a coating layer including a hydrophobic material.

A display device according to embodiments of the disclosure may comprise a stack portion, a cover glass disposed on the stack portion, a side sealing portion disposed on a side surface of the stack portion, and a coating layer disposed between the stack portion and the side sealing portion and including a hydrophobic material, wherein the stack portion includes a substrate, and an intermediate layer disposed on the substrate and including a sub intermediate layer and a lower adhesive layer disposed on the sub intermediate layer.

A display device according to embodiments of the disclosure may comprise a stack portion having a bending area, an inner side sealing portion disposed inside the stack portion in the bending area, an outer side sealing portion disposed outside the stack portion in the bending area, an inner coating layer disposed between the stack portion and the inner side sealing portion, and an outer coating layer disposed between the stack portion and the outer side sealing portion.

According to embodiments of the disclosure, there may be provided a display device having a side sealing portion as a structure for protecting a side portion of a stack portion in a display panel from external impact.

According to embodiments of the disclosure, there may be provided a display device that prevents cracks and/or delamination in an interlayer interface portion during a change in temperature, by disposing a coating layer between a side sealing portion and a stack portion in a display panel.

According to embodiments of the disclosure, there may be provided a display device capable of more effectively preventing cracks and/or delamination in an interlayer interface portion in a display panel by disposing a coating layer including a hydrophobic material.

According to embodiments of the disclosure, it is possible to prevent cracks or delamination that may occur in an interlayer interface in a display panel through a coating layer. It is possible to increase the yield of the display panel and hence reduce waste of production energy to enable process optimization by preventing cracks and delamination in the display panel during a manufacturing process of the display panel.

### BRIEF DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is a plan view illustrating a display device according to embodiments of the disclosure;

FIG. 2 is a cross-sectional view illustrating the first area of FIG. 1 according to embodiments of the disclosure;

FIG. 3 is a cross-sectional view illustrating the second area of FIG. 1 according to embodiments of the disclosure;

FIG. 4 is a cross-sectional view illustrating the first area of FIG. 1 according to embodiments of the disclosure;

FIG. 5 is a cross-sectional view illustrating the second area of FIG. 1 according to embodiments of the disclosure;

FIG. 6 is a cross-sectional view illustrating the first area of FIG. 1 according to embodiments of the disclosure;

FIG. 7 is a cross-sectional view illustrating changes in the first area of FIG. 1 according to temperatures according to embodiments of the disclosure;

FIG. 8 is a cross-sectional view illustrating the second area of FIG. 1 according to embodiments of the disclosure; and

FIG. 9 is a cross-sectional view illustrating changes in the second area of FIG. 1 according to temperatures according to embodiments of the disclosure.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only. ” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,” etc., each other via a fourth element. Here, the second element may be included in at least one of two or more elements that “are connected or coupled to,”“contact or overlap,”etc., each other.

To elaborate, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may”fully encompasses all the meanings of the term “can”.

Hereinafter, various embodiments of the disclosure are described in detail with reference to the accompanying drawings.

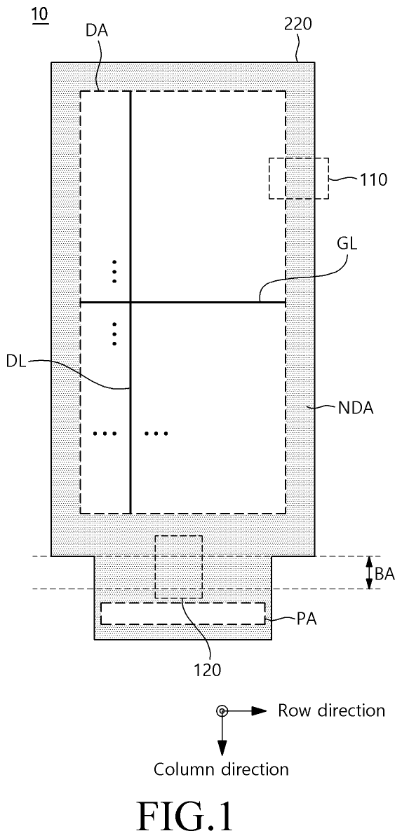

FIG. 1 is a plan view illustrating a display device according to embodiments of the disclosure.

Referring to FIG. 1, a display device according to embodiments of the disclosure may include a display panel 10 where an image is displayed and driving circuits for driving the display panel 10.

The display panel 10 according to embodiments of the disclosure may include a display area DA in which an image is displayed and a non-display area NDA disposed outside the display area DA.

The display area DA is an area where an image is displayed and may include a plurality of subpixels and may include a plurality of signal lines for driving the plurality of subpixels. The non-display area NDA may include a bending area BA and may further include a pad area PA where various driving circuits are connected.

The plurality of signal lines may include a plurality of data lines DL and a plurality of gate lines GL. The plurality of data lines DL and the plurality of gate lines GL may be disposed to cross each other. For example, the plurality of gate lines GL may be arranged in rows or columns, and the plurality of data lines DL may be arranged in columns or rows.

Each of the plurality of subpixels may include at least one transistor and may be configured in various ways depending on the type of display device.

For example, the display device according to embodiments of the disclosure may be a liquid crystal display device in which the display panel 10 does not emit light by itself or may be a self-luminous display device in which the display panel 10 emits light by itself. For example, the self-luminous display device may be an organic light emitting display device including organic material-based light emitting elements in the display panel, an inorganic light emitting display device including inorganic material-based light emitting elements in the display panel, or a quantum dot display device including quantum dot-based light emitting elements in the display panel.

For example, when the display device according to embodiments of the disclosure is a self-luminous display device, each subpixel in the display panel 10 may include various types of light emitting elements and at least one transistor for driving the light emitting elements and, in some cases, may include at least one capacitor.

The pad area PA included in the non-display area NDA is disposed on one side of the substrate 220 and may include a plurality of pads (metal patterns) where various driving circuits are electrically connected. For example, the driving circuit may include at least one of a driving chip, a flexible printed circuit (FPC), a printed circuit board (PCB), and a chip on film (COF). Although it is illustrated that the pad area PA is disposed on one side of the substrate 220, the shape and arrangement of the pad area PA are not limited thereto.

A signal (e.g., a voltage) input from an external module (driving circuit) connected (bonded) to the pad area PA may be transmitted to signal lines in the display area DA through connection lines. For example, the signal input through the pad area PA may include at least one of various gate driving-related signals, data signals, high-potential voltages, and low-potential voltages.

The non-display area NDA may include a bending area BA disposed on at least one side of the display panel 10 to bend or fold a portion of the substrate 220. For example, as the bending area BA is bent in the rear direction of the display panel 10, the external module bonded to the pad area PA may not be visually recognized. Further, as the bending area BA is bent, the size of the non-display area NDA visible from the top of the substrate 220 is reduced, thereby implementing a narrow bezel.

Referring to FIG. 1, the display panel 10 may include a first area 110 including a display area DA and a non-display area NDA adjacent to the display area DA, and a second area 120 including a bending area BA and at least a portion of the non-display area NDA adjacent to the bending area BA.

Hereinafter, the structure (particularly vertical structure) of the display panel 10 briefly described above is described in more detail. In the following description, in order to clearly describe the characteristics of the structure of the display panel 10, each of the structure of the first area 110 and the structure of the second area 120 is described.

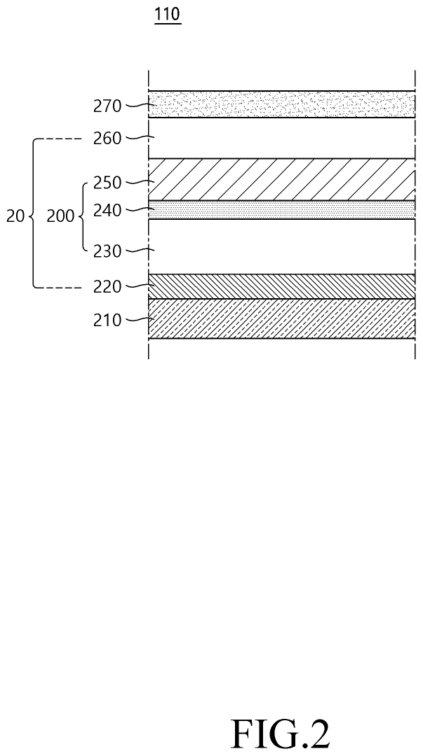

FIG. 2 is a cross-sectional view of a display panel 10 corresponding to the first area 110 of FIG. 1 according to embodiments of the disclosure.

Referring to FIG. 2, the first area 110 is an area disposed on at least one edge of the non-display area NDA and may include a display area DA and a non-display area NDA adjacent to the display area DA but not bent.

Referring to FIG. 2, a display device according to embodiments of the disclosure may include a substrate 220, an intermediate layer 200, an upper adhesive layer 260, and a cover glass 270.

The intermediate layer 200 is disposed on the substrate 220, and may include a sub intermediate layer 230 and a lower adhesive layer 240 disposed on the sub intermediate layer 230.

The upper adhesive layer 260 may be disposed on the intermediate layer 200, and the cover glass 270 may be disposed on the upper adhesive layer 260.

The substrate 220 may support various components of the display device. For example, the substrate 220 may be a member in which various components such as a plurality of metal layers and a plurality of insulating material layers are formed.

The substrate 220 may be formed of a material having flexibility. For example, the substrate 220 may be formed of a plastic material having flexibility. For example, flexible plastic materials may include at least one of polyimide (PI), polymethylmethacrylate (PMMA), polyethylene terephthalate (PET), polyethersulfone, and polycarbonate (PC), but are not limited thereto.

The sub intermediate layer 230 is disposed on the substrate 220 and may include at least one insulation layer. Here, the insulation layer may include an inorganic layer or an organic layer. The sub intermediate layer 230 may further include at least one metal layer.

For example, the sub intermediate layer 230 may include a plurality of light emitting element layers that emit light according to an image, a plurality of thin film transistors for driving the plurality of light emitting element layers, and a plurality of insulation layers and a plurality of metal layers for forming the plurality of thin film transistors.

The lower adhesive layer 240 is disposed on the sub intermediate layer 230, and may be formed of a transparent and adhesive material. For example, the lower adhesive layer 240 may be formed of at least one of an optically clear adhesive (OCA), an optically clear resin (OCR), and a pressure sensitive adhesive (PSA), but is not limited thereto.

Referring to FIG. 2, the intermediate layer 200 may further include a polarizer 250 disposed on the lower adhesive layer 240. The polarizer 250 may be attached to the sub intermediate layer 230 via the lower adhesive layer 240.

The polarizer 250 may selectively transmit light to reduce reflection of external light incident on the display device. For example, the display device may include various metal materials applied to thin film transistors, light emitting element layers, and lines. External light incident on the display device may be reflected by a metal material, and screen visibility of the display device may be reduced due to reflection of external light. Accordingly, the polarizer 250 may be disposed inside or outside the display panel to prevent reflection of external light, and screen visibility of the display device may be enhanced.

The upper adhesive layer 260 is disposed on the polarizer 250 and may be formed of a transparent and adhesive material. For example, the upper adhesive layer 260 may be formed of at least one of an optically clear adhesive (OCA), an optically clear resin (OCR), and a pressure sensitive adhesive (PSA), but is not limited thereto.

The cover glass 270 is disposed on the upper adhesive layer 260, and the cover glass 270 may be attached to the polarizer 250 via the upper adhesive layer 260.

The cover glass 270 may protect other components positioned under the cover glass 270 from external impact, heat, moisture, or the like. The cover glass 270 may be formed of a material having impact resistance and light transmittance. For example, the cover glass 270 may be a glass substrate or a film formed of a plastic material such as polymethylmethacrylate (PMMA), polyimide (PI), or polyethylene terephthalate (PET), but is not limited thereto.

Referring to FIG. 2, the display device according to embodiments of the disclosure may further include a back plate 210 disposed under the substrate 220.

The back plate 210 is a support member for maintaining the substrate 220 in a flat state. Since the substrate 220 may be formed of a material having flexibility, the back plate 210 may be used to maintain the shape of the display device, mechanical rigidity, or the like.

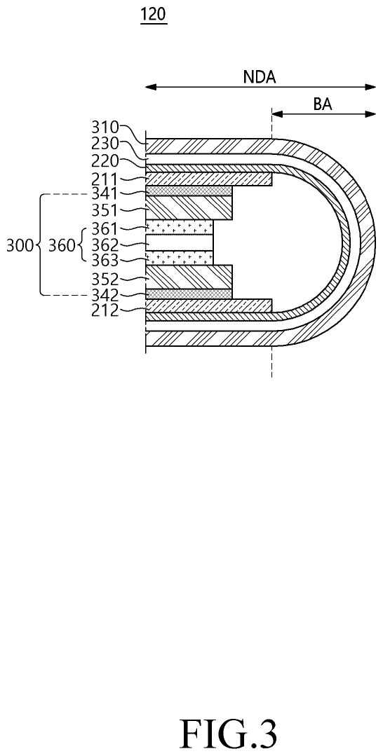

FIG. 3 is a cross-sectional view of a display panel 10 corresponding to the second area 120 of FIG. 1 according to embodiments of the disclosure.

Referring to FIG. 3, the second area 120 may include a bending area BA and at least a portion of the non-display area NDA adjacent to the bending area BA.

When the second area 120 and the first area 110 of FIG. 2 are disposed on the display panel 10, some components may be connected, and thus overlapping descriptions of some components are omitted.

Referring to FIG. 3, a display device according to embodiments of the disclosure may include a substrate 220, a sub intermediate layer 230, and a reinforcing member 310.

The substrate 220 may include a display area DA and a non-display area NDA including a bending area BA. In other words, the substrate 220 may be disposed to extend from the display area DA to the non-display area NDA including the bending area BA.

The sub intermediate layer 230 may be disposed on the substrate 220 and may extend from the display area DA to the non-display area NDA including the bending area BA. In other words, the sub intermediate layer 230 may be disposed outside the substrate 220.

The reinforcing member 310 may be disposed in the non-display area NDA including the bending area BA. In other words, the reinforcing member 310 may be disposed outside the sub intermediate layer 230.

The reinforcing member 310 may be formed of a material such as resin. For example, the reinforcing member 310 may include at least one of ultraviolet photocurable acrylic resin or thermosetting resin, but is not limited thereto.

The reinforcing member 310 may be a micro cover layer (MCL), but is not limited to the terminology.

Since the reinforcing member 310 may cover various connection lines disposed between the encapsulation portion of the display panel 10 and the pad area PA, moisture may be prevented from penetrating into the connection line while protecting the connection line from external impact.

In the bending area BA, other components than the substrate 220 and the connection line may be partially excluded to increase the flexibility of the display panel 10, so that the rigidity may be lowered. The reinforcing member 310 may supplement the rigidity of the bending area BA in which other components are partially excluded.

Referring to FIG. 3, the display device according to embodiments of the disclosure may include a first back plate 211 extending from the display area DA and disposed under the substrate 220.

The first back plate 211 may extend from the back plate 210 disposed under the substrate 220 of FIG. 2.

Referring to FIG. 3, a display device according to embodiments of the disclosure may include a second back plate 212 vertically spaced apart from the first back plate 211 and disposed to overlap at least a portion of the first back plate 211.

The second back plate 212 may be disposed on the same layer as the first back plate 211 before bending the bending area BA of the display panel 10.

Referring to FIG. 3, the display device according to embodiments of the disclosure may further include a connection member 300 disposed between the first back plate 211 and the second back plate 212 and connecting the first back plate 211 and the second back plate 212.

The connection member 300 may further include a first sub adhesive layer 341, a first metal plate 351, a second sub adhesive layer 342, a second metal plate 352, and a sub connection member 360.

The first sub adhesive layer 341 is disposed on a lower surface of the first back plate 211, and may be formed of a material having transparent and adhesive properties. For example, the first sub adhesive layer 341 may be formed of at least one of optically clear adhesive (OCA), optically clear resin (OCR), and pressure sensitive adhesive (PSA), but is not limited thereto.

The first metal plate 351 may be disposed on a lower surface of the first sub adhesive layer 341, and the first metal plate 351 may be attached to the first back plate 211 via the first sub adhesive layer 341.

The second sub adhesive layer 342 is disposed on an upper surface of the second back plate 212, and may be formed of a material having transparent and adhesive properties. For example, the second sub adhesive layer 342 may be formed of at least one of optically clear adhesive (OCA), optically clear resin (OCR), and pressure sensitive adhesive (PSA), but is not limited thereto.

The second metal plate 352 may be disposed on an upper surface of the second sub adhesive layer 342, and the second metal plate 352 may be attached to the second back plate 212 via the second sub adhesive layer 342.

The first metal plate 351 and the second metal plate 352 may be formed of a material having rigidity and high thermal conductivity in order to support and protect the display panel 10 on the rear surface of the substrate 220. Further, the first metal plate 351 and the second metal plate 352 may be formed of opaque metal to prevent light from leaking to the rear of the display panel 10.

For example, the first metal plate 351 and the second metal plate 352 may be formed of at least one of aluminum (Al), copper (Cu), zinc (Zn), silver (Ag), gold (Au), iron (Fe), stainless steel (SUS), Invar, or the like, but are not limited thereto.

The sub connection member 360 may be disposed between the first metal plate 351 and the second metal plate 352.

When the display panel 10 corresponding to the bending area BA is bent so that the pad area PA of the display panel 10 is disposed on the rear surface of the display panel 10, a restoring force for returning to the state before bending may act on the display panel 10.

The sub connection member 360 may function as a fixing member that fixes the bent display panel 10 to maintain the bending shape.

The sub connection member 360 may be a double-sided tape having an adhesive property capable of fixing the first metal plate 351 and the second metal plate 352.

Further, the sub connection member 360 may be a cushion layer. Thus, as the sub connection member 360 is disposed, the external impact applied to the display panel 10 may be alleviated.

Referring to FIG. 3, the sub connection member 360 may further include a base layer 362 and a first sub connection layer 361 and a second sub connection layer 363 respectively formed on two opposite surfaces of the base layer 362.

The sub connection member 360 may be fixed to the first metal plate 351 by the first sub connection layer 361, and may be fixed to the second metal plate 352 by the second sub connection layer 363.

The base layer 362 may be a support layer for maintaining the shape of the sub connection member 360.

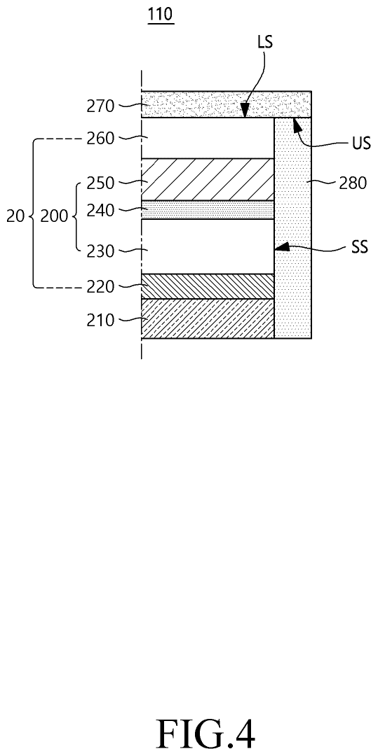

FIG. 4 is a cross-sectional view of a display panel 10 corresponding to the first area 110 of FIG. 1 according to embodiments of the disclosure.

Referring to FIG. 4, a display device according to embodiments of the disclosure may include a side sealing portion 280 disposed outside a stack portion 20 including the substrate 220, the intermediate layer 200, and the upper adhesive layer 260.

The side sealing portion 280 may be disposed outside the stack portion 20 to protect the display panel 10. For example, the side sealing portion 280 may protect the display panel 10 from external impacts applied to the side surfaces SS of the stack portion 20. Further, the side sealing portion 280 may prevent moisture and oxygen from flowing into the side surface SS of the stacked portion 20.

Referring to FIG. 4, the cover glass 270 may extend outward from a portion overlapping the upper adhesive layer 260, and a lower surface LS of the cover glass 270 may contact an upper surface US of the side sealing portion 280.

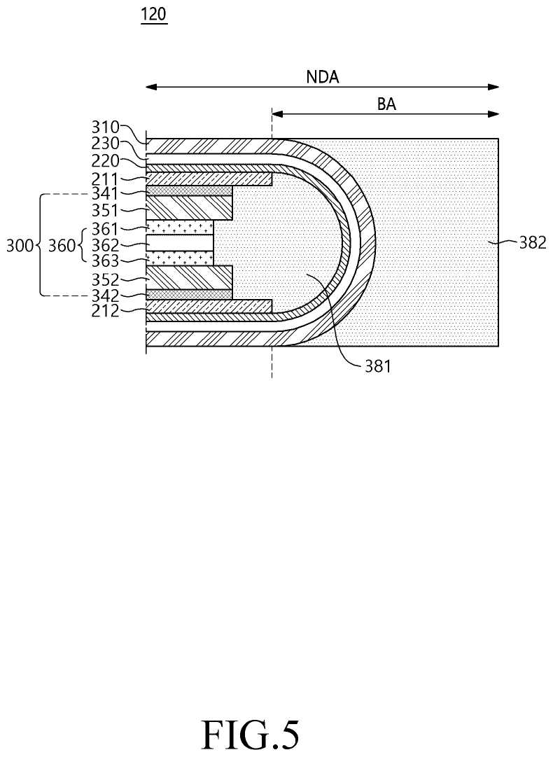

FIG. 5 is a cross-sectional view of a display panel 10 corresponding to the second area 120 of FIG. 1 according to embodiments of the disclosure.

Referring to FIG. 5, in the non-display area NDA and the bending area BA, the inner side sealing portion 381 may be disposed inside the portion where the substrate 220 is bent. In other words, the inner side sealing portion 381 may be disposed to fill an internal void generated when the display panel 10 is bent, and the first back plate 211 and the second back plate 212 are connected through the connection member 300.

Referring to FIG. 5, the outer side sealing portion 382 may be disposed outside the reinforcing member 310 in the bending area BA.

The display panel 10 may be protected by disposing the inner side sealing portion 381 and the outer side sealing portion 382 on two opposite sides of the portion where the substrate 220 and the sub intermediate layer 230 are bent. For example, the inner side sealing portion 381 and the outer side sealing portion 382 may protect the substrate 220 and the sub intermediate layer 230 from external impacts applied to the bending area BA. Further, the inner side sealing portion 381 and the outer side sealing portion 382 may prevent moisture and oxygen from entering from the outside of the display panel 10.

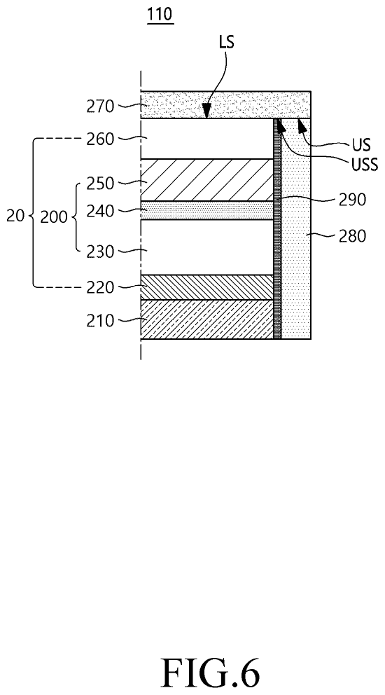

FIG. 6 is a cross-sectional view of a display panel 10 corresponding to the first area 110 of FIG. 1 according to embodiments of the disclosure.

Referring to FIG. 6, a display device according to embodiments of the disclosure may include a coating layer 290 disposed between a stack portion 20 including a substrate 220, an intermediate layer 200, and an upper adhesive layer 260 and a side sealing portion 280.

As the coating layer 290 is disposed between the stack portion 20 and the side sealing portion 280, mutual influence between the deformation of the stack portion 20 according to the temperature change and the deformation of the side sealing portion 280 according to the temperature change may be reduced.

For example, even if the ambient temperature of the display device is changed to be higher or lower than room temperature, the coating layer 290 may prevent the deformation of the side sealing portion 280 from affecting the stack portion 20, or the deformation of the stack portion 20 from affecting the side sealing portion 280.

For example, the coating layer 290 may be disposed to surround at least one edge of the non-display area NDA.

For example, according to the display device according to embodiments of the disclosure, the coating layer 290 may include a hydrophobic material.

For example, the hydrophobic material may be a polymer material having a low surface energy equal to or less than a predefined value. For example, the surface energy of the hydrophobic material may be about 30 mN/m or less.

For example, the hydrophobic material having low surface energy may include at least one of a fluorine-based hydrophobic material, a silicon-based hydrophobic material, and a saturated alkyl-based hydrophobic material.

For example, the fluorine-based hydrophobic material may include at least one of perfluoropolyether (PFPE) and fluoroolefin-based fluoroelastomers. The silicon-based hydrophobic material may include poly(dimethylsiloxane) (PDMS). The saturated alkyl-based hydrophobic material may include at least one of poly(tetramethylene oxide), poly(ethylene oxide), poly(oxetanes), polyisoprene, and polybutadiene.

The coating layer 290 may reduce a deviation in change between the sub intermediate layer 230 and the lower adhesive layer 240 according to a change in temperature.

Hereinafter, a case where the coating layer 290 reduces the deviation in change between the sub intermediate layer 230 and the lower adhesive layer 240 at a temperature below room temperature is described in more detail.

A change rate according to a change in temperature of the side sealing portion 280 according to embodiments of the disclosure may be larger than a change rate according to a change in temperature of the stack portion 20 including the substrate 220, the intermediate layer 200, and the upper adhesive layer 260.

According to embodiments of the disclosure, the “change rate” of any component (e.g., the side sealing portion 280, the substrate 220, the intermediate layer 200, the upper adhesive layer 260 or the like) may be a size change rate or a volume change rate.

Alternatively, the “change rate” may include a contraction change rate (contraction rate) and an expansion change rate (expansion rate). The contraction rate may be defined as a ratio (ΔS/S) of the size change amount ΔS of the corresponding component that contracts and decreases according to a temperature change to the size S of the corresponding component at room temperature. The expansion rate may be defined as a ratio ΔS/S of the size change amount ΔS of the corresponding component that expands and increases according to a temperature change to the size S of the corresponding component at room temperature.

For example, at a low temperature below room temperature, the side sealing portion 280 may contract more than the stack portion 20. In other words, at a low temperature below room temperature, the contraction change rate of the side sealing portion 280 may be larger than the contraction change rate of the stack portion 20. At a temperature higher than room temperature, the side sealing portion 280 may expand more than the stack portion 20. In other words, at a temperature higher than room temperature, the expansion change rate of the side sealing portion 280 may be larger than the expansion change rate of the stack portion 20.

The side sealing portion 280 may include a material having such a change rate characteristic. For example, the side sealing portion 280 may include a polymer material having a relatively large change rate according to a temperature change compared to the materials of other components (e.g., the stack portion 20, etc.).

Due to the behavior of the side sealing portion 280 according to the temperature change, a crack may occur at the interface between the sub intermediate layer 230 and the lower adhesive layer 240 when evaluating the thermal shock of the display panel 10 during the manufacturing process of the display panel 10. The display panel 10 may be defective.

When evaluating the thermal shock of the display panel 10, a situation in which a crack occurs in the upper portion of the sub intermediate layer 230 is described as follows.

The sub intermediate layer 230 and the lower adhesive layer 240 may include materials having different change rates according to a temperature change. In other words, the material of the sub intermediate layer 230 and the material of the lower adhesive layer 240 may have different change rates according to a temperature change.

The sub intermediate layer 230 has a property of contracting at a temperature below room temperature. At a temperature below room temperature, the contraction direction of the sub intermediate layer 230 and the contraction direction of the side sealing portion 280 may be opposite to each other. In other words, at a temperature below room temperature, the sub intermediate layer 230 may contract in a direction opposite to the direction in which the side sealing portion 280 contracts.

The lower adhesive layer 240 may be formed of a transparent and adhesive material. The lower adhesive layer 240 may have a strong adhesive force to the side sealing portion 280. Among the components of the stack portion 20, the lower adhesive layer 240 may have a stronger adhesive force to the side sealing portion 280.

When the side sealing portion 280 contracts at a temperature below room temperature, the lower adhesive layer 240 may be adhered to the contracting side sealing portion 280 and expand while being stretched.

At a temperature below room temperature, the direction in which the sub intermediate layer 230 contracts and the direction in which the lower adhesive layer 240 expands may be opposite to each other. Accordingly, at the interface between the sub intermediate layer 230 and the lower adhesive layer 240, stress may be applied to each of the sub intermediate layer 230 and the lower adhesive layer 240. Therefore, a crack may be generated in the upper portion of the sub intermediate layer 230.

According to embodiments of the disclosure, the coating layer 290 is disposed between the lower adhesive layer 240 and the side sealing portion 280, so that the lower adhesive layer 240 and the side sealing portion 280 may be separated from each other. Therefore, at temperatures below room temperature, the lower adhesive layer 240 may not expand in the opposite direction to the direction in which the sub intermediate layer 230 contracts due to the coating layer 290, so that the deviation in change due to temperature changes between the sub intermediate layer 230 and the lower adhesive layer 240 may be reduced.

As a result, stress applied to the interface between the sub intermediate layer 230 and the lower adhesive layer 240 is also reduced, and cracks occurring in the upper portion of the sub intermediate layer 230 may be prevented.

Further, since the adhesive force between the coating layer 290 and the side sealing portion 280 is much smaller than that between the coating layer 290 and the stack portion 20, even if the side sealing portion 280 contracts at temperatures below room temperature, the coating layer 290 is not affected by the side sealing portion 280. In other words, at a temperature below room temperature, the coating layer 290 may be spaced apart from the side sealing portion 280, and may move integrally with the stack portion 20.

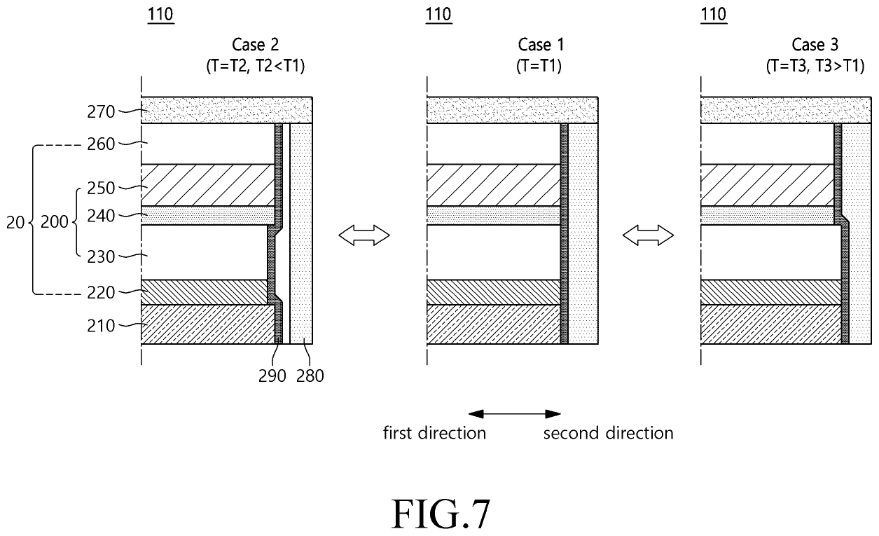

The temperature-specific behavior of the stack portion 20, the coating layer 290, and the side sealing portion 280 is described below in FIG. 7.

Referring to FIG. 6, the cover glass 270 may extend outward from a portion overlapping the upper adhesive layer 260, and a lower surface LS of the cover glass 270 may contact an upper surface USS of the coating layer 290 and an upper surface US of the side sealing portion 280.

FIG. 7 is a cross-sectional view illustrating changes in the first area 110 of FIG. 1 according to temperatures according to embodiments of the disclosure.

According to embodiments of the disclosure, the first temperature T1 may represent room temperature.

Referring to FIG. 7, when the ambient temperature of the display device is the first temperature T1, the stack portion 20 including the substrate 220, the intermediate layer 200, and the upper adhesive layer 260 and the side sealing portion 280 may not contract or expand.

According to embodiments of the disclosure, the second temperature T2 may be a temperature less than room temperature.

Referring to FIG. 7, when the ambient temperature of the display device is the second temperature T2, the coating layer 290 may be spaced apart from the side sealing portion 280.

Referring to FIG. 7, when the ambient temperature of the display device is the second temperature T2, the substrate 220 and the sub intermediate layer 230 may contract in a first direction, and the first side sealing portion 280 may contract in a second direction different from the first direction.

According to embodiments of the disclosure, the third temperature T3 may indicate a temperature exceeding room temperature.

Referring to FIG. 7, when the ambient temperature of the display device is the third temperature T3, the upper adhesive layer 260, the lower adhesive layer 240, and the polarizer 250 may contract in the first direction, and the side sealing portion 280 overlapping the upper adhesive layer 260, the lower adhesive layer 240, and the polarizer 250 may expand in the first direction.

Referring to FIG. 7, a change rate according to a change in temperature of the polarizer 250 may be different from at least one of a change rate according to a change in temperature of the sub intermediate layer 230 and a change rate according to a change in temperature of the lower adhesive layer 240.

Referring to FIG. 7, a change in size according to a change in temperature of the back plate 210 may be smaller than a change in size according to a change in temperature of the sub intermediate layer 230 and a change in size according to a change in temperature of the lower adhesive layer 240.

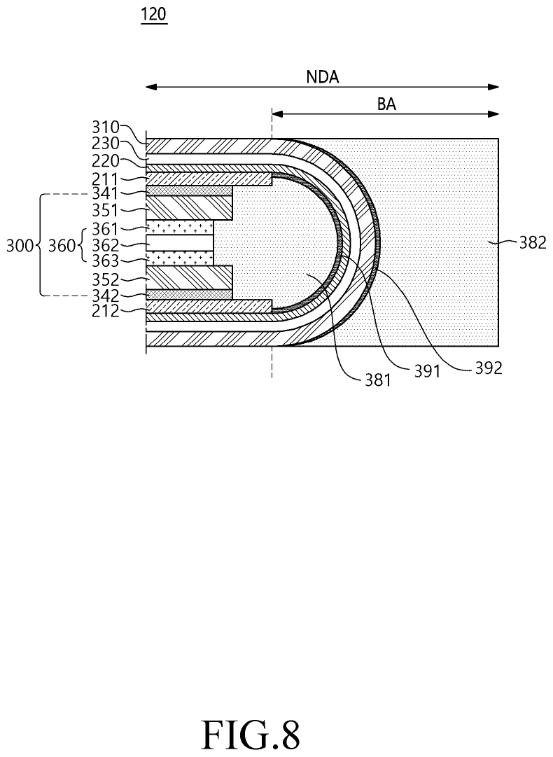

FIG. 8 is a cross-sectional view of a display panel 10 corresponding to the second area 120 of FIG. 1 according to embodiments of the disclosure.

Referring to FIG. 8, an inner coating layer 391 may be disposed between the substrate 220 and the inner side sealing portion 381, and one end and the other end of the inner coating layer 391 may contact the first back plate 211 and the second back plate 212, respectively.

Referring to FIG. 8, an outer coating layer 392 may be disposed between the reinforcing member 310 and the outer side sealing portion 382.

As the inner coating layer 391 and the outer coating layer 392 are disposed, deformation of the inner side sealing portion 381 and the outer side sealing portion 382 may be prevented from affecting the sub intermediate layer 230, even if the ambient temperature of the display device is changed to be higher or lower than room temperature.

For example, according to the display device according to embodiments of the disclosure, the inner coating layer 391 and the outer coating layer 392 may include a hydrophobic material.

For example, the hydrophobic material may be a polymer material having a low surface energy equal to or less than a predefined value. For example, the surface energy of the hydrophobic material may be about 30 mN/m or less.

For example, the hydrophobic material having low surface energy may include at least one of a fluorine-based hydrophobic material, a silicon-based hydrophobic material, and a saturated alkyl-based hydrophobic material.

For example, the fluorine-based hydrophobic material may include at least one of perfluoropolyether (PFPE) and fluoroolefin-based fluoroelastomers. The silicon-based hydrophobic material may include poly(dimethylsiloxane) (PDMS). The saturated alkyl-based hydrophobic material may include at least one of poly(tetramethylene oxide), poly(ethylene oxide), poly(oxetanes), polyisoprene, and polybutadiene.

The inner coating layer 391 and the outer coating layer 392 may maintain a balance between compressive stress and tensile stress applied on one side and the other side of the sub intermediate layer 230 when temperature is changed.

Hereinafter, a case where the inner coating layer 391 and the outer coating layer 392 maintain the balance between compressive stress and tensile stress applied on one side and the other side of the sub intermediate layer 230 at a temperature below room temperature is described in more detail.

A change rate according to a change in temperature of the inner side sealing portion 381 and the outer side sealing portion 382 according to embodiments of the disclosure may be larger than a change rate according to a change in temperature of the substrate 220, the sub intermediate layer 230, and the reinforcing member 310.

According to embodiments of the disclosure, the “change rate” of any component (e.g., the inner side sealing portion 381, the outer side sealing portion 382, the substrate 220, the sub intermediate layer 230, the reinforcing member 310 or the like) may be a size change rate or a volume change rate.

Alternatively, the “change rate” may include a contraction change rate (contraction rate) and an expansion change rate (expansion rate). The contraction rate may be defined as a ratio (ΔS/S) of the size change amount ΔS of the corresponding component that contracts and decreases according to a temperature change to the size S of the corresponding component at room temperature. The expansion rate may be defined as a ratio ΔS/S of the size change amount ΔS of the corresponding component that expands and increases according to a temperature change to the size S of the corresponding component at room temperature.

For example, at a low temperature below room temperature, the inner side sealing portion 381 and the outer side sealing portion 382 may contract more than the substrate 220, the sub intermediate layer 230, and the reinforcing member 310. In other words, at a low temperature below room temperature, the contraction change rate of the inner side sealing portion 381 and the outer side sealing portion 382 may be larger than the contraction change rate of the substrate 220, the sub intermediate layer 230, and the reinforcing member 310. At a temperature higher than room temperature, the inner side sealing portion 381 and the outer side sealing portion 382 may expand more than the substrate 220, the sub intermediate layer 230, and the reinforcing member 310. In other words, at a temperature higher than room temperature, an expansion change rate of the inner side sealing portion 381 and the outer side sealing portion 382 may be larger than an expansion change rate of the substrate 220, the sub intermediate layer 230, and the reinforcing member 310.

The inner side sealing portion 381 and the outer side sealing portion 382 may include a material having such a change rate characteristic. For example, the inner side sealing portion 381 and the outer side sealing portion 382 may include a polymer material having a relatively large change rate according to a change in temperature compared to the materials of other components (e.g., the substrate 220, the sub intermediate layer 230, the reinforcing member 310, etc.).

Due to the behavior of the inner side sealing portion 381 and the outer side sealing portion 382 according to a change in temperature, delamination may occur between a plurality of layers in the bent portion of the sub intermediate layer 230 when the display panel 10 is evaluated for thermal shock during the manufacturing process of the display panel 10. The display panel 10 may be defective.

When evaluating the thermal shock of the display panel 10, a situation in which delamination occurs between a plurality of layers in the bent portion of the sub intermediate layer 230 is described as follows.

The substrate 220, the sub intermediate layer 230, and the reinforcing member 310 may be bent and fixed at a constant curvature in the bending area BA.

In this case, compressive stress may be applied to a surface disposed close to the center of curvature of each of the substrate 220, the sub intermediate layer 230, and the reinforcing member 310, and tensile stress may be applied to a surface opposite to the surface to which compressive stress is applied.

When the substrate 220, the sub intermediate layer 230, and the reinforcing member 310 are bent, the compressive stress acting on one side of each of the substrate 220, the sub intermediate layer 230, and the reinforcing member 310 and the tensile stress acting on the other side may be balanced to maintain the bent shape.

There may be an adhesive force between the inner side sealing portion 381 and the substrate 220, and there may be an adhesive force between the outer side sealing portion 382 and the reinforcing member 310.

When the inner side sealing portion 381 contracts at a temperature below room temperature, the substrate 220 may be pulled in a direction in which the inner side sealing portion 381 contracts due to the adhesive force with the contracting inner side sealing portion 381.

When the outer side sealing portion 382 contracts at a temperature below room temperature, the reinforcing member 310 may be pulled in a direction in which the outer side sealing portion 382 contracts due to the adhesive force with the contracting outer side sealing portion 382.

At a temperature below room temperature, the direction in which the substrate 220 is pulled and the direction in which the reinforcing member 310 is pulled around the sub intermediate layer 230 may be opposite to each other. As a result, a balance between compressive stress and tensile stress acting on one side and the other side, respectively, of the sub intermediate layer 230 may collapse.

If the balance of compressive stress and tensile stress acting on one side and the other side, respectively, of the sub intermediate layer 230 collapses, a layer that may be disposed on the neutral surface of the sub intermediate layer 230 that may include a plurality of layers may crack.

The neutral surface may be defined as a surface where the state of stress becomes 0 during bending. In other words, if the balance between compressive stress and tensile stress acting on one side and the other side, respectively, of the sub intermediate layer 230 collapses, the state of stress on the neutral surface of the sub intermediate layer 230 may not be zero.

Cracks occurring in the sub intermediate layer 230 may cause delamination between the plurality of layers in the sub intermediate layer 230.

According to embodiments of the disclosure, as the inner coating layer 391 is disposed between the substrate 220 and the inner side sealing portion 381, the substrate 220 and the inner side sealing portion 381 may be separated from each other. Therefore, at temperatures below room temperature, the substrate 220 may not be able to be pulled in the direction in which the inner side sealing portion 381 contracts by the inner coating layer 391.

According to embodiments of the disclosure, as the outer coating layer 392 is disposed between the reinforcing member 310 and the outer side sealing portion 382, the reinforcing member 310 and the outer side sealing portion 382 may be separated from each other. Therefore, at temperatures below room temperature, the reinforcing member 310 may not be able to be pulled in the direction in which the outer side sealing portion 382 contracts by the outer coating layer 392.

As a result, the force that pulls the substrate 220 and the reinforcing member 310 as the inner side sealing portion 381 and the outer side sealing portion 382 contract on two opposite sides of the sub intermediate layer 230 is removed, so that the balance between compressive stress and tensile stress acting on one side and the other side, respectively, of the sub intermediate layer 230 may be maintained.

Therefore, it is possible to prevent cracks from occurring in a layer that may be disposed on the neutral surface of the bent sub intermediate layer 230, and delamination of the plurality of layers in the sub intermediate layer 230.

Further, since the adhesive force between the inner coating layer 391 and the inner side sealing portion 381 is much smaller than that between the inner coating layer 391 and the substrate 220, the inner coating layer 391 is not affected by the inner side sealing portion 381 even if the inner side sealing portion 381 contracts at a temperature below room temperature. In other words, the inner coating layer 391 may be spaced apart from the inner side sealing portion 381 at a temperature less than room temperature.

Since the adhesive force between the outer coating layer 392 and the outer side sealing portion 382 is much smaller than that between the outer coating layer 392 and the reinforcing member 310, even if the outer side sealing portion 382 contracts at a temperature below room temperature, the outer coating layer 392 is not affected by the outer side sealing portion 382. In other words, the outer coating layer 392 may be spaced apart from the outer side sealing portion 382 at a temperature less than room temperature.

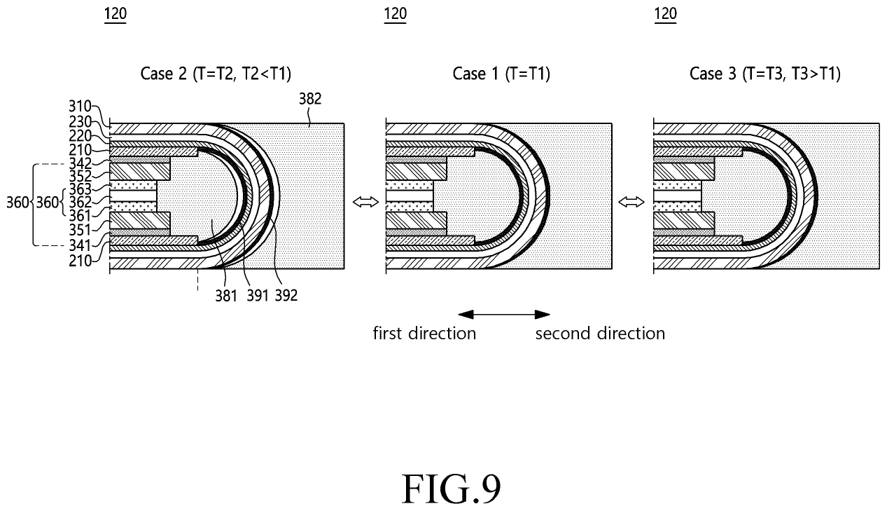

The temperature-specific behavior of the inner coating layer 391, the outer coating layer 392, the inner side sealing portion 381, and the outer side sealing portion 382 is described in FIG. 9.

FIG. 9 is a cross-sectional view illustrating changes in the second area 120 of FIG. 1 according to temperatures according to embodiments of the disclosure.

The first temperature T1, the second temperature T2, and the third temperature T3 are the same as those of FIG. 7, and thus a repeated description thereof may be omitted.

Referring to FIG. 9, when the ambient temperature of the display device is the first temperature T1, the inner side sealing portion 381 and the outer side sealing portion 382 may not contract or expand.

Referring to FIG. 9, when the ambient temperature of the display device is the second temperature T2, the inner side sealing portion 381 may be contracted in the first direction or spaced apart from the inner coating layer 391, and the outer side sealing portion 382 may be contracted in the second direction or spaced apart from the outer coating layer 392.

Referring to FIG. 9, when the ambient temperature of the display device is the third temperature T3, the inner side sealing portion 381 may expand in the second direction, and the outer side sealing portion 382 may expand in the first direction.

The inner coating layer 391, the substrate 220, the sub intermediate layer 230, the reinforcing member 310, and the outer coating layer 392 disposed between the inner side sealing portion 381 and the outer side sealing portion 382 may have strength enough to withstand pressure applied as the inner side sealing portion 381 and the outer side sealing portion 382 expand in the second direction and the first direction, respectively. Accordingly, each of the inner side sealing portion 381 and the outer side sealing portion 382 may have no change at a temperature exceeding room temperature, i.e., according to an increase in temperature.

The foregoing embodiments of the disclosure are briefly described below.

A display device according to embodiments of the disclosure may comprise a substrate, an intermediate layer disposed on the substrate and including a sub intermediate layer and a lower adhesive layer disposed on the sub intermediate layer, an upper adhesive layer disposed on the intermediate layer, a cover glass disposed on the upper adhesive layer, a side sealing portion disposed outside a stack portion including the substrate, the intermediate layer, and the upper adhesive layer, and a coating layer disposed between the stack portion and the side sealing portion and including a hydrophobic material.

According to the display device according to embodiments of the disclosure, the sub intermediate layer and the lower adhesive layer may include materials having different change rates according to a change in temperature.

According to the display device according to embodiments of the disclosure, a deviation in change in size according to a change in temperature between the sub intermediate layer and the lower adhesive layer may be decreased by the coating layer.

According to the display device according to embodiments of the disclosure, the intermediate layer may further include a polarizer disposed on the lower adhesive layer, and a change rate according to a change in temperature of the polarizer may be different from at least one of a change rate according to a change in temperature of the sub intermediate layer and a change rate according to a change in temperature of the lower adhesive layer.

According to the display device according to embodiments of the disclosure, when an ambient temperature of the display device exceeds room temperature, the upper adhesive layer, the lower adhesive layer, and the polarizer may contract in a first direction, and the side sealing portion overlapping the upper adhesive layer, the lower adhesive layer, and the polarizer may expand in the first direction.

The display device according to embodiments of the disclosure may further comprise a back plate disposed under the substrate. A change in size according to a change in temperature of the back plate may be smaller than a change in size according to a change in temperature of the sub intermediate layer and a change in size according to a change in temperature of the lower adhesive layer.

According to the display device according to embodiments of the disclosure, the cover glass may extend outward from a portion overlapping the upper adhesive layer, and a lower surface of the cover glass may contact an upper surface of the coating layer and an upper surface of the side sealing portion.

According to the display device according to embodiments of the disclosure, the coating layer may be disposed surrounding at least a portion of at least one edge of a non-display area.

According to the display device according to embodiments of the disclosure, the hydrophobic material may include at least one of a fluorine-based hydrophobic material, a silicon-based hydrophobic material, and a saturated alkyl-based hydrophobic material.

According to the display device according to embodiments of the disclosure, when an ambient temperature of the display device is less than room temperature, the coating layer may be spaced apart from the side sealing portion, and the substrate and the sub intermediate layer may contract in a first direction, and the first side sealing portion may contract in a second direction different from the first direction.

A display device according to embodiments of the disclosure may comprise a substrate including a display area and a non-display area including a bending area, an inner side sealing portion disposed inside a bent portion of the substrate in the bending area, a sub intermediate layer disposed on the substrate, extending from the display area, and disposed outside the bent portion of the substrate, a reinforcing member disposed outside the sub intermediate layer, an outer side sealing portion disposed outside the reinforcing member in the bending area, an inner coating layer disposed between the substrate and the inner side sealing portion, and an outer coating layer disposed between the reinforcing member and the outer side sealing portion.

According to the display device according to embodiments of the disclosure, the inner coating layer and the outer coating layer may include a hydrophobic material.

According to the display device according to embodiments of the disclosure, the hydrophobic material may include at least one of a fluorine-based hydrophobic material, a silicon-based hydrophobic material, and a saturated alkyl-based hydrophobic material.

The display device according to embodiments of the disclosure may further comprise a first back plate extending from the display area and disposed under the substrate, and a second back plate vertically spaced apart from the first back plate and overlapping at least a portion of the first back plate.

The display device according to embodiments of the disclosure may further comprise a connection member disposed between the first back plate and the second back plate and connecting the first back plate and the second back plate.

According to the display device according to embodiments of the disclosure, the connection member may include a first sub adhesive layer disposed on a lower surface of the first back plate, a first metal plate disposed on a lower surface of the first sub adhesive layer, a second sub adhesive layer disposed on an upper surface of the second back plate, a second metal plate disposed on an upper surface of the second sub adhesive layer, and a sub connection member disposed between the first metal plate and the second metal plate.

According to the display device according to embodiments of the disclosure, one end and another end of the inner coating layer may contact the first back plate and the second back plate, respectively.

According to the display device according to embodiments of the disclosure, when an ambient temperature of the display device is less than room temperature, the inner side sealing portion may contract or may be spaced apart from the inner coating layer, and the outer side sealing portion may contract or may be spaced apart from the outer coating layer.

According to the display device according to embodiments of the disclosure, when an ambient temperature of the display device exceeds room temperature, each of the inner side sealing portion and the outer side sealing portion may have no change according to an increase in temperature.

The display device according to embodiments of the disclosure may further comprise a coating layer disposed to surround at least one edge of the non-display area.

According to embodiments of the disclosure described above, there may be provided a display device having a side sealing portion as a structure for protecting a side portion of a stack portion in a display panel from external impact.

According to embodiments of the disclosure, there may be provided a display device that prevents cracks and/or delamination in an interlayer interface portion during a change in temperature, by disposing a coating layer between a side sealing portion and a stack portion in a display panel.

According to embodiments of the disclosure, there may be provided a display device capable of more effectively preventing cracks and/or delamination in in a display panel by disposing a coating layer including a hydrophobic material.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a stack portion;
a cover glass on the stack portion;
a side sealing portion on a side surface of the stack portion; and
a coating layer between the stack portion and the side sealing portion, the coating layer including a hydrophobic material,
wherein the stack portion includes:
a substrate; and
an intermediate layer on the substrate and including a sub intermediate layer and a lower adhesive layer on the sub intermediate layer.

2. The display device of claim 1, wherein the sub intermediate layer and the lower adhesive layer include materials having different change rates according to a change in temperature, and
wherein a deviation in change in size according to a change in temperature between the sub intermediate layer and the lower adhesive layer is decreased by the coating layer.

3. The display device of claim 2, wherein the intermediate layer further includes a polarizer on the lower adhesive layer,
wherein the stack portion further includes an upper adhesive layer on the intermediate layer, and
wherein a change rate according to a change in temperature of the polarizer is different from at least one of a change rate according to a change in temperature of the sub intermediate layer and a change rate according to a change in temperature of the lower adhesive layer.

4. The display device of claim 3, wherein when an ambient temperature of the display device exceeds room temperature, the upper adhesive layer, the lower adhesive layer, and the polarizer contract in a first direction, and the side sealing portion overlapping the upper adhesive layer, the lower adhesive layer, and the polarizer expand in the first direction.

5. The display device of claim 2, further comprising a back plate disposed under the substrate,
wherein a change in size according to a change in temperature of the back plate is smaller than a change in size according to a change in temperature of the sub intermediate layer and a change in size according to a change in temperature of the lower adhesive layer.

6. The display device of claim 1, wherein the cover glass extends outward from a portion overlapping the stack portion, and
wherein a lower surface of the cover glass contacts an upper surface of the coating layer and an upper surface of the side sealing portion.

7. The display device of claim 1, wherein the coating layer surrounds at least one edge of the substrate.

8. The display device of claim 1, wherein the hydrophobic material includes at least one of a fluorine-based hydrophobic material, a silicon-based hydrophobic material, and a saturated alkyl-based hydrophobic material.

9. The display device of claim 1, wherein when an ambient temperature of the display device is less than room temperature, the coating layer is spaced apart from the side sealing portion, the substrate and the sub intermediate layer contract in a first direction, and the first side sealing portion contracts in a second direction different from the first direction.

10. The display device of claim 1, wherein a change rate according to a change in temperature of the side sealing portion is larger than a change rate according to a change in temperature of the stack portion.

11. The display device of claim 1, wherein an adhesive force between the coating layer and the side sealing portion is smaller than an adhesive force between the coating layer and the stack portion.

12. A display device, comprising:
a stack portion having a display area and a non display area including a bending area;
an inner side sealing portion disposed inside the stack portion in the bending area;
an outer side sealing portion disposed outside the stack portion in the bending area;
an inner coating layer between the stack portion and the inner side sealing portion; and
an outer coating layer between the stack portion and the outer side sealing portion,
wherein the stack portion includes:
a substrate;
a sub intermediate layer on the substrate; and
a reinforcing member on the sub intermediate layer.

13. The display device of claim 12, wherein the inner coating layer and the outer coating layer include a hydrophobic material.

14. The display device of claim 13, further comprising:
a first back plate extending from the display area and disposed under the substrate;
a second back plate vertically spaced apart from the first back plate and overlapping at least a portion of the first back plate; and
a connection member between the first back plate and the second back plate and connecting the first back plate and the second back plate.

15. The display device of claim 14, wherein the connection member includes:
a first sub adhesive layer on a lower surface of the first back plate;
a first metal plate on a lower surface of the first sub adhesive layer;
a second sub adhesive layer on an upper surface of the second back plate;
a second metal plate on an upper surface of the second sub adhesive layer; and
a sub connection member between the first metal plate and the second metal plate.

16. The display device of claim 14, wherein one end and another end of the inner coating layer contact the first back plate and the second back plate, respectively.

17. The display device of claim 12, wherein when an ambient temperature of the display device is less than room temperature, the inner side sealing portion contracts or is spaced apart from the inner coating layer, and the outer side sealing portion contracts or is spaced apart from the outer coating layer.

18. The display device of claim 12, wherein when an ambient temperature of the display device exceeds room temperature, each of the inner side sealing portion and the outer side sealing portion has no change in size according to an increase in temperature.

19. The display device of claim 12, wherein a change rate according to a change in temperature of each of the inner side sealing portion and the outer side sealing portion is larger than a change rate according to a change in temperature of the stack portion.

20. The display device of claim 12, wherein an adhesive force between the inner coating layer and the inner side sealing portion is smaller than an adhesive force between the inner coating layer and the stack portion, and
an adhesive force between the outer coating layer and the outer side sealing portion is smaller than an adhesive force between the outer coating layer and the stack portion.
